(19) United States
(12) Patent Application Publication
(10) Pub. No.: US 2009/0199999 A1
(43) Pub. Date: Aug. 13, 2009

(54) Electric Component with Two-Phase Cooling Device and Method for Manufacturing

(76) Inventors: Gerhard Mitic, München (DE); Eckhard Wolfgang, München (DE)

Correspondence Address: STAAS & HALSEY LLP, SUITE 700, 1201 NEW YORK AVENUE, N.W., WASHINGTON, DC, 20005, US

(21) Appl. No.: 11/989,130

(22) PCT Filed: Jul. 19, 2006
(86) PCT No.: PCT/EP2006/064412

§ 371 Date: Feb. 20, 2009

(30) Foreign Application Priority Data
Jul. 19, 2005 (DE) 10 2005 033 713.9

(51) Int. Cl. F28D 15/00; H01R 43/00

(52) U.S. Cl. 165/104.26; 165/104.33; 29/854

(57) ABSTRACT

At least one electric component, such as a power semiconductor component, has at least a two-phase cooling device having at least one evaporator. The evaporator has a liquefier with a structured liquefier surface for evaporating a cooling fluid, formed by an electric connecting line making electrical contact with an electric contact face of the component. The connecting line cools the power semiconductor component and a module equipped therewith. Isothermal cooling with a low thermal loading of the power semiconductor component or of the module is possible by virtue of the two-phase cooling device acting as an evaporating bath cooling system. The device is applied in the planar contact-making technology with a large surface by providing an electric component with an electric contact face and producing the electric connecting line to the evaporator surface on the contact face of the component.

### CROSS REFERENCE TO RELATED APPLICATIONS

This application is based on and hereby claims priority to German Application No. 10 2005 033 713.9 filed on Jul. 19, 2005, the contents of which are hereby incorporated by reference.

### BACKGROUND

Described below is an apparatus with at least one electric component and at least one cooling device for dissipating heat from the component, the cooling device having at least one two-phase cooling device having at least one evaporator, and the evaporator having a patterned evaporator surface for evaporating a cooling fluid. In addition, a method for manufacturing the apparatus is specified.

During operation of the electric component, high power losses may result in the development of a considerable amount of heat. For reliability of the component, it may be necessary to efficiently dissipate the heat produced during operation. A two-phase cooling device, for example, is used for this purpose.

### SUMMARY

the compact apparatus described below can be easily manufactured and includes an electric component and a two-phase cooling device. Specifically, the apparatus has at least one electric component and at least one cooling device for dissipating heat from the component. The cooling device has at least one two-phase cooling device having at least one evaporator, and the evaporator has a patterned evaporator surface for evaporating a cooling fluid. The patterned evaporator surface is formed by an electrical connecting line for electrically contact-connecting an electrical contact area of the component.

A method for manufacturing includes providing an electric component having an electrical contact area and producing the electrical connecting line with the evaporator surface on the contact area of the component.

The electrical connecting line is configured for electrically contact-connecting the component as an evaporator of the two-phase cooling device. Large quantities of heat develop during operation of power components, in particular, on account of the high currents which are transported using the connecting line. As a result of the fact that the connecting line itself forms the evaporator surface, these quantities of heat can be directly dissipated at the location at which they are produced. Many conductor materials, for example copper or aluminum, are not only electrically but also thermally highly conductive, with the result that an efficient heat conducting path away from the component is additionally provided using the connecting line as an evaporator. In addition, efficient cooling results with the aid of the patterned evaporator surface. The patterned evaporator surface has an evaporator surface which is larger than an unpatterned surface and is available for the evaporating operation (cf. below).

For efficient cooling, in one particular configuration, the two-phase cooling device has a condenser having a patterned condenser surface for condensing the cooling fluid. The patterned condenser surface also has a condenser surface which is larger than an unpatterned surface and is available for the condensing operation. The particular configurations of the patterned evaporator surface which are described below may also relate to the condenser surface.

A two-phase cooling device essentially includes an evaporator for evaporating a cooling fluid, a condenser for condensing the cooling fluid and a fluid channel for transporting the cooling fluid both in the liquid phase and in the gaseous phase. The fluid channel forms a vapor chamber of the two-phase cooling device, in which the cooling fluid is evaporated on the evaporator. The cooling fluid is condensed from the vapor chamber on the condenser.

The two-phase cooling device allows a high heat flux density by using the heat of evaporation and the heat of condensation of the cooling fluid (coolant). The high heat flux density results as follows: the evaporator is thermally conductively connected to the electric component by the electrical connecting line. The heat produced during operation of the electric component is transferred to the evaporator. The heat transferred results in evaporation of the liquid cooling fluid. The cooling fluid changes from the liquid phase into the gaseous phase. In this case, the cooling fluid absorbs the heat of evaporation. The gaseous cooling fluid passes through the fluid channel to the condenser. The condenser is thermally conductively connected to a heat sink. The gaseous cooling fluid is condensed in the condenser. The cooling fluid changes from the gaseous phase into the liquid phase. In this case, the heat of condensation is dissipated to the heat sink. The involvement of the two phase changes of the cooling fluid results in a high heat flux density and thus in efficient transport of heat away from the component to the heat sink.

The cooling fluid condensed on the condenser is transported back to the evaporator again through the fluid channel. There is thus a closed materials circuit. Depending on the configuration of the fluid channel and the type of return transport, a distinction is made between two types of two-phase cooling devices: in the case of a so-called “thermosiphon”, return transport is essentially effected on the basis of the force of gravity. In contrast to this, return transport essentially takes place on the basis of capillary forces in the case of a so-called “heat pipe”.

In one particular configuration, the two-phase cooling. device is in the form of a boiling bath cooling system. In this case, the evaporator or evaporator surface is situated in a cooling fluid bath (boiling bath). The evaporator surface and the vapor chamber are not in direct contact but rather are in indirect contact via the liquid cooling fluid. Evaporation of the cooling fluid results in the typical formation of vapor bubbles in the liquid cooling fluid. The boiling bath is preferably used not only to accommodate the evaporator or evaporator surface but also to accommodate and cool the entire component.

An electrically non-conductive, that is to say electrically insulating, cooling fluid is used for cooling purposes. In particular, halogenated and, advantageously, fluorinated hydrocarbons are used as the cooling fluid. For example, the fluorinated hydrocarbon is Fluorinert®. The connecting line has, in particular, an electrically and thermally highly conductive metal. The metal is copper or aluminum, in particular.

In one particular configuration, the connecting line has an electrochemical deposit in order to form the evaporator surface. In particular, the electrochemical deposit has copper. Copper can be electrodeposited in a simple manner and in relatively thick layer thicknesses from a solution containing copper salts. The layer thicknesses may be up to several 100 μm. A current carrying capacity needed to operate the component, for example a power semiconductor component, can thus be provided.

The apparatus may have any desired electric component which has to be efficiently cooled for stable operation. In one particular configuration, the component is a semiconductor component and, in particular, is a power semiconductor component. The power semiconductor component is selected from the group of an IGBT, a diode, a MOSFET, a thyristor and a bipolar transistor.

According to one particular configuration, the component is arranged on a substrate in such a manner that the electrical contact area of the component faces away from the substrate. An efficient heat-conducting path away from the component is provided with the aid of the two-phase cooling device and the particular patterning of the evaporator surface. This efficient heat-conducting path does not lead via the substrate.

A single electric component may be provided for a single substrate. In one particular configuration, a plurality of components are arranged on a substrate (module). The components may be wired to one another by corresponding connecting lines. Each of the components is advantageously thermally conductively connected to one or more two-phase cooling devices. It is thus possible to efficiently cool each of the components. It is also conceivable to connect all of the components on the substrate to a single two-phase cooling device. For example, the evaporator surface is formed by a plurality of patterned connecting lines. Efficient distribution of heat over the entire substrate is thus possible. No heat peaks occur. Heat peaks could result in lasting damage to the entire module including the components and the substrate.

In one particular configuration, an electrical insulation film is laminated onto the component and the substrate, with the result that a surface contour, which is formed by the component and the substrate, is reproduced in a surface contour of the insulation film, which faces away from the component and the substrate. The surface contour (topography) of the component and of the substrate is copied by the insulation film. The insulation film follows the surface contour of the component and of the substrate. This concerns, in particular, corners and edges of the component and of the substrate. The surface contour of the component and of the substrate is copied by virtue of the insulation film being laminated onto the component and onto the substrate. The laminating-on operation results in particularly intimate and permanent contact between the insulation film and the electric component and between the insulation film and the substrate. The insulation film is preferably laminated on in a vacuum.

In one particular configuration, the connecting line with the patterned evaporator surface is applied to the insulation film. An electrical plated-through hole through the insulation film is provided in this case for the purpose of contact-connecting the electrical contact area of the component. To manufacture such an apparatus, an insulation film is laminated on, for example. At least one window is then opened in the insulation film. Opening the window exposes the electrical contact area of the component. The window is opened, for example, by laser ablation or a photolithography process. Electrically conductive conductor material is then deposited.

In the case of an electric component in the form of a semiconductor component or power semiconductor component, it has proved to be worthwhile to deposit different conductor materials to form a multilayer connecting line. The connecting line includes metalization layers which are arranged above one another. For example, the contact area of the power semiconductor component includes aluminum. A lowermost metalization layer which is directly applied to the contact area of the power semiconductor component includes titanium, for example, and acts as an adhesion promoting layer. A metalization layer which is arranged above it includes a titanium/tungsten alloy which acts as a barrier layer for copper ions. An electrodeposited copper layer forms the termination. This copper layer is patterned in order to form the patterned evaporator surface. Electrical, mechanical and/or electrochemical patterning is carried out, in particular, for patterning.

The structure of the evaporator surface is dimensioned in such a manner that efficient evaporation of the cooling fluid is possible. Therefore, the structure depends on the quantity of heat which is produced during operation of the component and has to be dissipated. In addition, the structure depends on the cooling fluid and on the conductor material from which the evaporator surface is formed. It is thus expedient to ensure sufficient wettability. This also applies with regard to the configuration of the two-phase cooling device as a boiling bath cooling system. Boiling delays, for example, are prevented by sufficient wettability.

Particularly efficient cooling is achieved when capillary forces can be used to subsequently deliver the cooling fluid in liquid form to “hot” points, so-called “hot spots”, of the evaporator surface, at which evaporation primarily takes place. In one particular configuration, the patterned evaporator surface therefore has a capillary structure. In this case, local hot points are cooled by the evaporation process in a particularly good manner, which enables isothermal operation of the component. In one particular configuration, the capillary structure has a size which is selected from the range of 0.1 μm to 1000 μm inclusive and, in particular, from the range of 10 μm to 100 μm inclusive. These sizes prove to be particularly advantageous. The capillary structure has capillaries. A capillary is a cavity, in particular a small-volume cavity with a size from the stated ranges. The capillaries represent open surface structures. As a result of the open surface structures, the cooling fluid is transported on the basis of capillary forces. For efficient transport and thus for efficient cooling, the capillary structure, the conductor material which forms the capillary structure and the cooling fluid are matched to one another, with the result that good wettability of the evaporator surface having the capillary structure with the cooling fluid is provided. It is particularly advantageous if the evaporator surface having the capillary structure is part of the cooling channel of the two-phase cooling device. When the two-phase cooling device is configured as a “heat pipe”, in particular, this configuration ensures efficient transport of the cooling fluid and thus efficient cooling. This configuration also has the particular advantage that the likelihood of the evaporator surface “running dry” is reduced in comparison with another two-phase cooling device. When the evaporator surface is “running dry”, the evaporator surface is at least partially no longer wetted with the cooling fluid, which is also referred to as the “Leidenfrost phenomenon”. Therefore, cooling by evaporation does not take place. The result may be overheating of, and thus damage to, the component or the entire apparatus. With the aid of the patterned evaporator surface, this is associated with an increase in the critical heat flux density, up to. which thermal operation is possible.

In one particular configuration, the two-phase cooling device has a means for setting a boiling temperature of the cooling fluid. This is particularly advantageous when the apparatus or the component is operated at different temperatures. Temperature fluctuations which occur during operation are also conceivable. The means can be used to compensate for the different temperatures or temperature fluctuations without impairing the cooling power of the two-phase cooling device. The component is efficiently cooled at any time.

The means for setting the boiling temperature may be, for example, an external pressure generator which is in contact with the vapor chamber. This makes it possible to increase or decrease the vapor pressure of the cooling fluid in the vapor chamber. The boiling temperature is consequently decreased or increased. According to one particular configuration, the means for setting the boiling temperature has a means for changing a vapor chamber of the two-phase cooling device, which vapor chamber is in contact with the evaporator surface of the evaporator. As already mentioned above, the evaporator surface and the vapor chamber may be in direct or indirect contact with one another. A change in the vapor chamber includes, in particular, a change in the vapor chamber volume of the vapor chamber. For this purpose, the means for changing the vapor chamber has an expandable bellows, in particular. The bellows has a variable bellows volume. The bellows volume can be directly formed by the vapor chamber in this case. It is also conceivable for a bellows chamber, which forms the bellows volume, and the vapor chamber, which forms the vapor chamber volume, to be indirectly connected by a pressure transmission device. Such a pressure transmission device is, for example, an elastically deformable membrane. A change in the pressure in the bellows chamber is transmitted to the vapor chamber by the membrane. This may result in a change in the pressure in the vapor chamber or in a change in the vapor chamber volume.

In order to manufacture the apparatus, an already prefabricated, patterned connecting line can be connected to the contact area of the component. However, the connecting line is preferably patterned only when it has already been connected to the contact area of the component. According to one particular configuration, the following further operations are therefore carried out to produce the connecting line: electrically conductive conductor material is applied, and the electrically conductive conductor material which has been applied is patterned during and/or after the application of the electrically conductive conductor material.

The electrically conductive conductor material can be applied from the vapor phase (vapor deposition method), for example using PVD (Physical Vapor Deposition) or CVD (Chemical Vapor Deposition) methods. However, as described above, the conductor material is preferably electrochemically deposited. The electrochemical deposit is produced.

The surface of the conductor material which has been applied is patterned, for example, during application by using a suitable patterning mask. Patterning by material removal is also conceivable. Therefore, electrical, mechanical and/or electromechanical patterning is preferably used for patterning.

In summary, the apparatus has the following fundamental advantages:
It is possible to efficiently dissipate heat from a component.
Local hot points, so-called “hot spots”, are cooled by the evaporation process in a particularly good manner.
The apparatus is compact. Manufacture of the patterned evaporator surface can be easily integrated in already existing manufacturing processes.
The patterned evaporator surface results in efficient distribution of heat. In addition, isothermal cooling of the component and, in particular, isothermal cooling of a module having a plurality of components are possible.
The efficient distribution of heat and isothermal cooling of the component or of the module result in a thermal load which is low in comparison with the prior art and thus in increased reliability.

### BRIEF DESCRIPTION OF THE DRAWINGS

These and other aspects and advantages will become more apparent and more readily appreciated from the following description of exemplary embodiments, taken in conjunction with the accompanying drawings of which:

FIG. 1 is a lateral cross section through the apparatus.

FIG. 2 is a lateral cross section through a section of the apparatus.

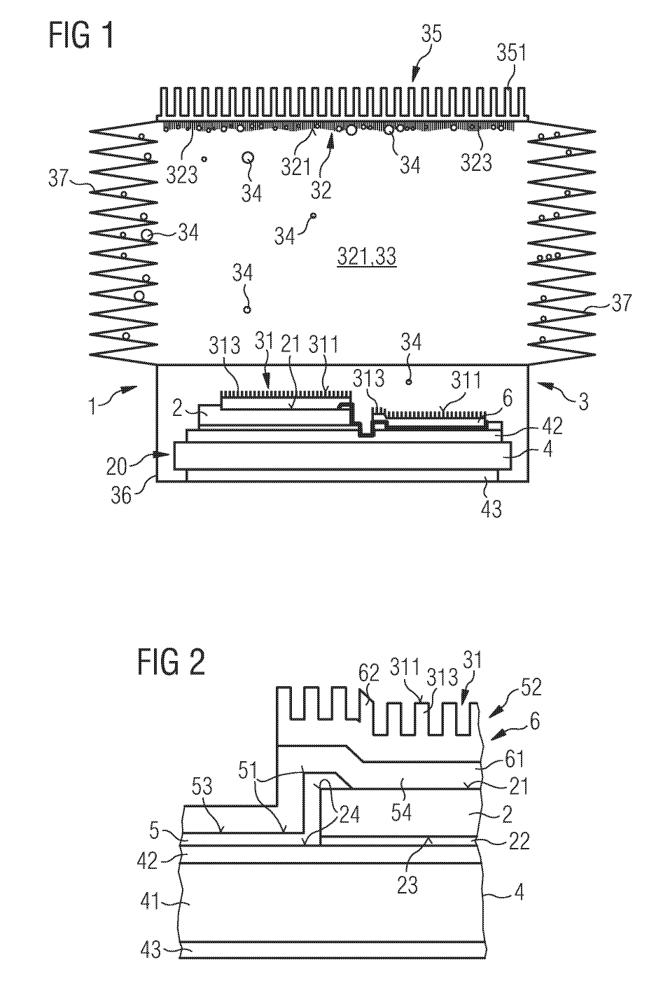

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

The exemplary embodiments respectively relate to an apparatus 1 of at least one electric component 2 and at least one cooling device 3 for dissipating heat which is produced during operation of the component 2.

The electric component 2 is a power semiconductor component in the form of a MOSFET. In an alternative embodiment, the power semiconductor component 2 is an IGBT.

The power semiconductor component 2 is part of an overall module 20 in which a plurality of power semiconductor components 2 (not illustrated) are arranged and wired on a single, common substrate 4. The substrate 4 is a DCB (Direct Copper Bonding) substrate. In the case of the DCB substrate 4, a ceramic layer 41 is provided with copper layers 42 and 43 on both sides.

The power semiconductor component 2 has an electrical contact area 21 which is electrically contact-connected over a large area. For this purpose, the power semiconductor component 2 is soldered to one of the copper layers 42 and 43 of the substrate 4 in such a manner that that contact area 21 of the power semiconductor component 2 which is to be contact-connected faces away from the substrate 4. A solder trace 22 results between the power semiconductor component 2 and the corresponding copper layer 42 of the substrate 4. The copper layer 42 and the solder trace 22 are used to electrically contact-connect a further electrical contact area 23 of the power semiconductor component 2.

In order to electrically contact-connect the contact area 21 of the power semiconductor component 2, an electrical insulation film 5 is laminated onto the component 2 and the substrate 4 in such a manner that a surface contour 24, which is formed by the power semiconductor component 2 and the substrate 4, is reproduced in the surface contour 51 of the insulation film 5, which faces away from the power semiconductor component 2 and the substrate 4 (cf. FIG. 2). Insulation material of the insulation film 5 is subsequently removed from the insulation film 5 in order to expose the contact area 21 of the power semiconductor component 2. This is carried out by laser ablation. A window 52 is produced in the insulation film. The contact area 21 of the power semiconductor component 2 is freely accessible.

After the contact area 21 has been exposed, the electrical connecting line 6 for electrically contact-connecting the contact area 21 is applied. For this purpose, electrically conductive materials are applied, in patterned form, to the contact area 21 and to a film surface 53 of the insulation film 5, which faces away from the substrate 4 and the power semiconductor component 2. A multilayer electrical connecting line 6 including a plurality of electrically conductive layers 61 is produced. The electrical plated-through hole 54 through the insulation film 5 is produced at the same time.

An electrochemical copper deposit 62 forms the termination of the multilayer connecting line 6. For this purpose, copper is electrodeposited from a suitable solution containing copper ions.

The cooling device is a two-phase cooling device 3 having an evaporator 31 for a cooling fluid 34. The cooling fluid is a Fluorinert®. The evaporator 31 has an evaporator surface 311. The cooling fluid 34 is evaporated on the evaporator surface 311. Evaporation takes place in the vapor chamber 312 of the two-phase cooling device 3. In addition to the evaporator 31, the two-phase cooling device 3 has a condenser 32 for condensing the cooling fluid 34. The cooling fluid 34 condenses on a condenser surface 321.

The evaporator 31 or the evaporator surface 311 is immersed in a boiling bath 36 containing the cooling fluid 34. A boiling bath cooling system is present. As an alternative to this, the two-phase cooling device 3 is in the form of a “heat pipe”. The cooling fluid 34 is transported from the condenser 32 to the evaporator 31 by capillary forces. In this case, the evaporator surface 311 having the capillary structure 313 is part of the fluid channel 33.

The evaporator 31 is connected to the condenser 32 via the vapor chamber 312. The gaseous cooling fluid 34 passes to the condenser 32 through the vapor chamber 312. The vapor chamber 312 constitutes the fluid channel 33 of the two-phase cooling device 3.

The condenser 32 is in thermally conductive contact with a heat sink 35. The heat sink 35 has a copper block having cooling ribs 351. In this manner, the heat of condensation which is released when the cooling fluid 34 condenses on the condenser surface 321 is efficiently dissipated.

For efficient heat dissipation from the component 2, the evaporator surface 311 is patterned. The patterned evaporator surface is formed by the electrical connecting line 6 for contact-connecting the electrical contact area 21 of the component 2.

The patterned evaporator surface 311 has a capillary structure 313. Liquid or condensed cooling fluid 34 is continuously introduced via the capillary structure 313 using capillary forces. In addition, the patterning results in an increase in the size of the effective evaporator surface 311 which can be used for evaporation. This results in efficient cooling of the power semiconductor component 2.

In order to improve the cooling power, the condenser surface 321 is likewise patterned. For this purpose, the condenser surface 321 likewise has a corresponding capillary structure 323.

In order to produce the capillary structure 313, copper is electrodeposited in patterned form. This is effected using a suitable patterning mask. In an alternative embodiment, the capillary structure 313 is electromechanically produced following the electrodeposition of copper. Copper is removed. The capillary structure 323 of the condenser surface is produced in a corresponding manner.

In order to compensate for a change in temperature or a temperature fluctuation, which can occur during operation of the power semiconductor component, a means 37 for setting the boiling temperature of the cooling fluid 34 is provided. The means 37 for setting the boiling temperature is a means for changing the vapor chamber 312. The means for changing the vapor chamber is an expandable bellows which can be used to change the vapor chamber volume. As a result of the fact that the boiling temperature of the cooling fluid 34 can be set, it is possible to efficiently dissipate heat at any time, that is to say independently of the operating phase or the operating state of the power semiconductor component 2 or the module 20.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-18. (canceled)

19. An apparatus, comprising:
at least one electric component; and
at least one two-phase cooling device dissipating heat from said at least one electric component, having at least one evaporator with a patterned evaporator surface for evaporating a cooling fluid, the patterned evaporator surface formed by an electrical connecting line electrically contact-connecting an electrical contact area of said at least one electric component.

20. The apparatus as claimed in claim 19, the patterned evaporator surface having a capillary structure.

21. The apparatus as claimed in claim 20, wherein the capillary structure has a size selected from the range of 0.1 μm to 1000 μm inclusive.

22. The apparatus as claimed in claim 21, wherein the capillary structure has a size selected from the range of 10 μm to 100 μm inclusive.

23. The apparatus as claimed in claim 21, wherein said at least one two-phase cooling device includes means for setting a boiling temperature of the cooling fluid.

24. The apparatus as claimed in claim 23,
wherein said at least one two-phase cooling device includes a vapor chamber in contact with the evaporator surface of the at least one evaporator, and
wherein said means for setting the boiling temperature includes means for changing the vapor chamber of the two-phase cooling device.

25. The apparatus as claimed in claim 24, wherein said means for changing the vapor chamber includes an expandable bellows.

26. The apparatus as claimed in claim 25, wherein the connecting line has an electrochemical deposit forming the evaporator surface.

27. The apparatus as claimed in claim 26, wherein the electrochemical deposit includes copper.

28. The apparatus as claimed in claim 27, wherein the at least one two-phase cooling device further includes a condenser having a patterned condenser surface for condensing the cooling fluid.

29. The apparatus as claimed in claim 28, wherein the at least one two-phase cooling device further includes a boiling bath accommodating the at least one component.

30. The apparatus as claimed in claim 29, wherein each of the at least one component is a semiconductor component.

31. The apparatus as claimed in claim 30, wherein each semiconductor component is a power semiconductor component selected from the group of an insulated gate bipolar transistor, a diode, a metal-oxide semiconductor field-effect transistor, a thyristor and a bipolar transistor.

32. The apparatus as claimed in claim 30,
further comprising a substrate, and
wherein each of said at least one electric component is arranged on said substrate with the electrical contact area facing away from said substrate.

33. The apparatus as claimed in claim 32, further comprising an electrical insulation film laminated onto said at least one electric component and said substrate, whereby a first surface contour formed by said at least one electric component and said substrate is reproduced in a second surface contour of said insulation film facing away from said at least one electric component and said substrate.

34. The apparatus as claimed in claim 33,
wherein the connecting line to the patterned evaporator surface is applied to the insulation film, and
wherein said insulation film includes an electrical plated-through hole providing a contact-connection to the electrical contact area of said at least one electric component.

35. A method for manufacturing an apparatus, comprising:
providing an electric component having an electrical contact area; and
producing an electrical connecting line, electrically contact-connecting the electrical contact area of the electric component, with a patterned evaporator surface for evaporating a cooling fluid, the electrical connecting line acting as a two-phase cooling device dissipating heat from the electric component.

36. The method as claimed in claim 35, wherein said producing comprises:
applying an electrically conductive conductor material to said electric component; and
patterning the electrically conductive conductor material at least one of during and after said applying of the electrically conductive material.

37. The method as claimed in claim 36, wherein said patterning includes at least one of electrical, mechanical and electromechanical patterning.
